(19) United States
(12) Patent Application Publication
(10) Pub. No.: US 2010/0262887 A1
(43) Pub. Date: Oct. 14, 2010

(54) High Integrity Data Network System and Method

(75) Inventor: Kevin H. Wilson, Baldwinsville, NY (US)

Correspondence Address: Howard IP Law Group, P.O. Box 226, Fort Washington, PA, 19034, US

(73) Assignee: LOCKHEED MARTIN CORPORATION, Bethesda, MD (US)

(21) Appl. No.: 12/422,660

(22) Filed: Apr. 13, 2009

(51) Int. Cl. H03M 13/27; H03M 13/05; G06F 11/10

(52) U.S. Cl. 714/758; 714/E11.032

(57) ABSTRACT

A system for transmitting information data packets over a network includes a plurality of parallel transmission channels, each receiving interleaved data words constituting the data packets. Each channel includes a corresponding check sum data generator to compute check sum data for a corresponding sequence of data words. A logic circuit responsive to the interleaved data words from each channel performs an arithmetic operation on the data words from those channels to generate a parity data stream onto a separate channel. A check sum data generator computes checksum data based on the parity data stream. An encoder device downstream from each checksum data generator encodes the data and checksum from each channel for serial transmission over a network.

### FIELD OF INVENTION

The present invention relates generally to data transmission systems and more particularly to a system and process for the recovery of data in networks disposed to transmission errors.

### BACKGROUND

State of the art wired (e.g. fiber optic and copper) networking equipment offers bit error rates (BERs) on the order of 1 in 10¹² bits. As the data transmission rates start to approach these BERs, the frequency of errors becomes problematic, particularly for the larger systems. For example, a typical sensor data network contained in a digital radar system may be operating at 4×10⁹ to 10×10⁹ bits per second, with dozens of these networks contained in the radar system. This means that, on average, somewhere in the system data is being corrupted by a communications error every 1 to 2 minutes or less. Given that these radars are real-time sensors operating at very high data rates it is not practical to employ traditional retransmission techniques to recover the erroneous data.

Typical methods for solving the aforementioned problem include: (a) buffering the data and using software protocols for error detection and retransmit requests; (b) forward error correction data with the data; (c) using fully redundant networks (though generally employed for full failover); (d) accepting the error. Data buffering requires significant memory buffering and processing overhead, as well as additional weight, power, space, and cost to the system due to added components. In the event of an error, retransmission of data interrupts the normal data flow, and in the event of excessive errors can prevent the data from getting through at all. Forward error correction data schemes require complex computations both at the sending end and at the receiving end if an error occurs. Fully redundant networking schemes have obvious cost, weight, power, and size implications because at least two networks are required. Error acceptance without correction is often intolerable to effective systems operation. An alternative solution that requires simpler computations, is reasonable in cost, weight, power, and size implications, and provides error correction as required for a particular application is highly desired.

### SUMMARY OF THE INVENTION

The present invention comprises a system for transmitting data comprising: a plurality of parallel transmission channels receiving interleaved data words of a block of data for transmission over a network. Each channel includes an associated check sum data generator to compute check sum associated with that channel's data words. A logic circuit computes parity data based on the interleaved data words from the respective channels to generate a parity data stream on a separate parity channel. A checksum generator associated with the parity channel is responsive to the parity data stream for providing parity check sum. An encoder arrangement encodes each of the transmission channel data words and checksum and parity data words and parity checksum for serial transmission over a physical network.

A receiver arrangement is responsive to the transmission from the physical network for receiving and decoding the transmitted data. A corresponding plurality of parallel receiver channels receives the decoded information and performs a corresponding checksum (e.g. a CRC check) on the received, decoded, transmitted data words to compute a checksum. The computed checksum associated with each channel is compared to the received, decoded checksum associated with that channel. Based on the comparison, a logic circuit determines that if an error exists in only one of the data channels, and not in the parity channel, the logic circuit causes a recovery circuit to reconstruct the information data words in the channel in error according to the information data words received from the remaining data channels and the received parity data.

A system for transmitting information data packets over a network includes a plurality of parallel transmission channels, each receiving interleaved data words constituting the data packets. Each channel includes a corresponding check sum data generator to compute check sum data for a corresponding sequence of data words. A logic circuit responsive to the interleaved data words from each channel performs an arithmetic operation on the data words from those channels to generate a parity data stream onto a separate channel. A check sum data generator computes checksum data based on the parity data stream. An encoder device downstream from each checksum data generator encodes the data and checksum from each channel for serial transmission over a network.

Another aspect of the invention comprises a system for receiving data comprising: a plurality of reception channels having associated check sum data checkers to compute check sum data associated with received data; and at least one channel for receiving parity and an associated check sum; and a comparator to compare the computed check sum of the check sum checker with the received associated check sum.

The present invention also comprises a system for correcting errors in information data transmitted over multiple transmission channels, comprising: a plurality of transmission channels conveying interleaved information data constituting a data block, each of the channels having a corresponding check sum device to compute a check sum associated with the information data conveyed via the channels; a processor for computing parity data based on the interleaved information data; a channel for transmitting the parity data and check sum data associated with the parity data. The system includes a transmitter arrangement which transfers the channel information data and channel checksum for each of the plurality of transmission channels, and the channel parity data and parity checksum for the parity channel, over a network. In addition, the system includes a corresponding plurality of reception channels having associated checksum devices to compute check sums associated with the transmitted information data. A corresponding channel is adapted to receive the transmitted parity data and associated parity check sum, the corresponding channel having an associated checksum device to compute a checksum associated with the transmitted parity data; and a logic circuit that compares the computed check sum of the transmitted information and parity data with reference data, wherein if an error is determined in only one of the data channels based on the comparison, and not in the parity channel, the logic circuit causes a recovery circuit to reconstruct the information data in the channel in error according to the information data received from the remaining data channels and the received parity data.

### BRIEF DESCRIPTION OF THE DRAWINGS

Understanding of the present invention will be facilitated by consideration of the following detailed description of the preferred embodiments of the present invention taken in conjunction with the accompanying drawings wherein:

FIG. 1 is a block diagram of a prior art communication and error recovery system.

FIG. 2 is a block diagram of a communication and error recovery system according to an embodiment of the present invention.

FIG. 3 is a process flow diagram for communications transmission, receipt, and error recovery according to an embodiment of the present invention.

### DETAILED DESCRIPTION

It is to be understood that the figures and descriptions of the present invention have been simplified to illustrate elements that are relevant for a clear understanding, while eliminating, for the purpose of clarity, many other elements found in typical communications systems and methods of making and using the same. Those of ordinary skill in the art may recognize that other elements and/or steps may be desirable in implementing the present invention. However, because such elements and steps are well known by those of ordinary skill in the art, and because they do not facilitate a better understanding of the present invention, a discussion of such elements and steps is not provided herein. Furthermore, while the present invention is described in relation to a radar system, it is understood that the invention is applicable to other complex systems wherein error correction of transmitted and/or received information data is required.

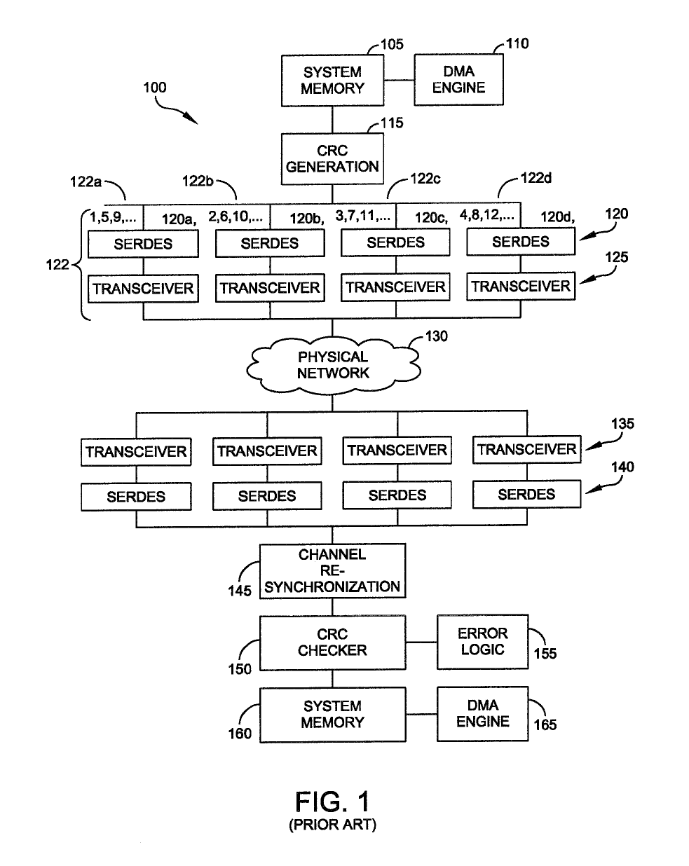

FIG. 1 illustrates a prior art architecture for a high speed data network 100 utilizing a transmission technique referred to as channel bonding to achieve high data rates. A typical prior art high speed data network 100 includes a direct memory access (DMA) engine 110 that transfers data to a system memory 105. Typically the DMA engine 110 transfers data in blocks of 16-bit words. As each data block or data word is formatted for transmission a cyclical redundancy check (CRC) generator 115 computes a check sum for the word, which is appended to the data stream. A check sum function produces as output a value of a certain fixed size. The CRC checksum may be used to detect accidental alteration of the data during transmission or storage. CRCs are typically simple to implement in binary hardware, such as a field programmable gate array (FPGA) and are additionally simple to analyze mathematically, making them efficient detectors for common errors caused by noise or other artifacts commonly found in transmission channels. CRC and check sum computations generally are well known by those of ordinary skill in the art of data storage and transmission and are not described further herein for purposes of brevity.

The data words output from CRC generator 115 in FIG. 1 are applied to a plurality of channels labeled generally as 122 which work in parallel to obtain a higher aggregate data rate. As shown in FIG. 1, four lower speed channels 122a, 122b, 122c, 122d operate in parallel to obtain a higher aggregate data rate. For example, one implementation of a 10 gigabit (Gb) Ethernet uses 4×2.5 Gb channels or lanes to achieve the required throughput. Such throughput is achieved utilizing components such as a serializer/deserializer (SERDES) 120. The data words output from CRC generator 115 are parsed and input into the SERDES as bytes having length n. In the example illustrated in FIG. 1, data is routed 16 bits at a time (parallel data) to each of the 4 SERDES devices 120a, 120b, 120c, 120d in interleaved fashion. As shown, first channel 122a includes SERDES 120a that receives bytes 1, 5, 9 . . . ; second channel 122b includes SERDES 120b that receives bytes 2, 6, 10, . . . ; third channel 122c includes SERDES 120c that receives bytes 3, 7, 11, . . . ; and fourth channel 122d includes SERDES 120d that receives bytes 4, 8, 12, . . . . Each SERDES 120 also encodes 16 bits into 20 bits (e.g., 8 bits/10 bit encoding) for transmission via corresponding transceivers 125 that support serial interfaces in high-speed data network applications. The four channel data is transmitted from the transceivers 125 over a physical network 130. The data travels over the network 130 on parallel channels that correspond to the channels 122. The physical network 130 may comprise any medium for data transmission such as: (a) four parallel twisted pair of copper lanes for electrical transmission, (b) four distinct wavelengths, if transmitted using fiber optics, or (c) four microwave transmitters and associated receivers, operating via a medium such as air. If the microwave receivers are point to point, they may operate at the same frequency and if they are over a single channel the transmission may be coded (e.g., CDMA, TDMA) or at different frequencies.

The data is received from network 130 by corresponding transceivers labeled generally as 135 and corresponding SERDES labeled generally as 140 at the receiving end. Each receiving SERDES 140 recovers a data clock to decode the data back to 16 bit parallel values and pass the data to a channel resynchronization module 145. The channel resynchronization module includes logic functions to reformat and/or realign the data into the original 16-bit parallel values.

Following reconstruction from disparate bytes into the original form, a CRC checker 150 receives the ordered data and calculates a CRC on the received data. The CRC is compared to the expected value to determine if the data's integrity is intact (i.e., no errors are detected). If the CRC is correct then the CRC value appended at transmit is stripped from the data stream and the data is stored in the receiving system's memory 160. The data is subsequently transferred via DMA engine 165 to service various applications. If the CRC is incorrect (i.e. an error is detected) then entire received data stream or packet is discarded and an error signal is sent to the error logic processing module 155 to register the error. Typically an error message is sent to the receiving system processor using means well known by those of ordinary skill in the art of data storage and transmission.

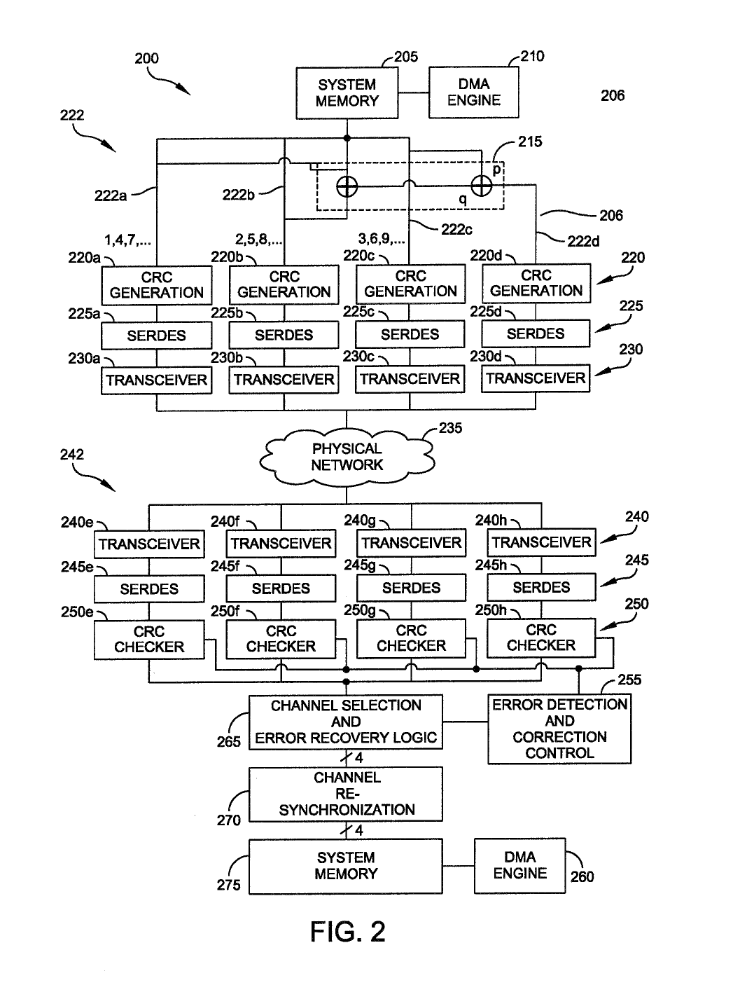

Referring now to FIG. 2, there is shown an exemplary architecture according to an embodiment of the present invention, whereby N+1 transmission channels are utilized to recover data in the event of a transmission error in one of the channels, where N transmission channels contain application (i.e. information) data and the N^{th}+1 transmission channel contains parity data formed according to the application data. FIG. 2 depicts a system 200 in a non-limiting embodiment of the invention that allows the placement of application data along with check sum data on three transmission channels 222a, 222b, and 222c, respectively. An additional transmission channel 222d operates to transmit parity data 206 related to each of the channels 222a, 222b, 222c application data. In one non-limiting embodiment of the invention, upon subsequent reception of the data from channels 222a, 222b, 222c by the receiving system 242, data errors can be recovered, provided the errors do not occur on more than one channel. As will be clear any number of channels designated generally as 222 may carry data, provided one channel is reserved for parity data 206.

In the illustrated embodiment, data packets comprising data blocks in the form of data words configured according to a given application, for example, are operated on by DMA engine 210. DMA engine 210 transfers data blocks as 16-bit words via system memory 205 to three parallel channels 222a, 222b, and 222c in an interleaved or round robin fashion. As data is transferred from the DMA engine 210 and system memory 205 into each of the three channels 222a, 222b, and 222c, a parity logic module 215 operates on the data words input into the first N channels (e.g. 222a, 222b, 222c in the non-limiting example of the invention illustrated) via exclusive-or operations to provide a parity data stream onto transmission channel 222d. In the non-limiting example of the invention illustrated, the logical operation for the “exclusive-or” results in a value of “true” if and only if exactly one of the operands p, q has a value of “true”. As indicated the N^{th}+1 channel is reserved for the parity data 206. The parity channel 222d data is computed via a simple and inexpensive exclusive-or operation. The exclusive-or operation may be implemented using a FPGA, for example. Other implementations are contemplated including ASICs as well as other electronic circuit configurations.

Still referring to FIG. 2, each channel 222a, 222b, 222c, and 222d includes a CRC logic check module (220a, 220b, 220c, and 220d) responsive to the received data words for computing a checksum that is appended to that data stream. In the exemplary embodiment, CRC module 220a performs CRC computations on data blocks (e.g. data words) 1, 4, 7, . . . ; CRC module 220b performs CRC computations on data words 2, 5, 8, . . . ; CRC module 220c performs CRC computations on data words 3, 6, 9, . . . ; and CRC module 220d performs CRC computations on the exclusive-or'd parity data 206. Check sum computations are well known to those skilled in data transmission. A check sum function uses input data from the data stream provided by the output from system memory 205 and the DMA engine 210 of any length and produces as output a value of a certain fixed size. A CRC check sum by way of example is used to detect alteration of the data during transmission or storage. Check sum means are typically simple to implement in binary hardware, such as via an FPGA and are additionally simple to analyze mathematically, making such devices efficient detectors for common errors caused by noise or other artifacts commonly found in transmission channels.

The data words and appended checksum data output from each CRC generator are input into the respective SERDES module 225a, 225b, 225c, and 225d as bytes having length n. In the example illustrated in FIG. 2, each of the SERDES devices encodes the data to 20 bits (8 b/10 b encoding) for transmission via corresponding transceivers 230 that support serial interfaces in high-speed data network applications. The encoded data representative of the application data and the check sum data associated with each channel 222a, 222b, 222c, and the data stream containing parity data 206 and checksum associated with channel 222d, are transmitted via the respective transceivers 230a, 230b, 230c, 230d over physical network 235, in similar fashion to that described in connection with FIG. 1.

The encoded data associated with each channel 222a, 222b, 222c, and 222d is received from network 235 by corresponding respective transceivers 240e, 240f, 240g, and 240h arranged in parallel and applied to corresponding decoders (e.g. SERDES) 245e, 245f, 245g, and 245h at the receiving end. Each SERDES labeled generally as 245 recovers a data clock to decode its data and reconstruct the data back to a 16-bit parallel data format.

A corresponding checksum (e.g. a cyclic redundancy check (CRC)) module labeled generally as 250 receives the output of the SERDES and computes a check sum to determine if any data received via the corresponding channel (e.g., 242e, 242f, 242g, or 242h) contains an error. The output of each CRC module (i.e. 250e, 250f, 250g, 250h) is input to error detection and correction control logic module 255. In one non-limiting embodiment, module 255 receives each of the N checksum inputs (N=4) and determines if all the check sums from channels, 242e, f, g, h indicate that the data for each channel is received and is intact, i.e., no errors detected (e.g. all inputs=0), then the data from the received channels, 242e, 242f, 242g is passed on to system memory 275 (via modules 265, 270, for example) for further application processing with no requirement for correction. If one and only one of the check sums from channels, 242e, 242f, 242g, 242h indicate that the data is not intact, (i.e., an error is detected via error detection and correction control 255) on one of the received channels, e, f, g, h, (e.g. one single input=1) then the erroneous channel data can be recovered by using the data from the remaining three error free channels via the channel selection and error recovery logic module 265. In one non-limiting embodiment of the invention an exclusive-or computation of the remaining three error-free channels (including for example the parity data channel) may be employed to recover the channel data having disclosed an error. A channel resynchronization 270 function reformats the data blocks to ensure the data is in the order required by system memory 275 and DMA engine 260. Upon reformatting, the data is then applied to memory 275 and DMA engine 260. If the determined error(s) emanated from only the parity channel (e.g., channel h), then no error recovery is required. If more than one check sum detects an error (i.e. errors are determined to exist in multiple channels) then the entire data packet from all channels is discarded.

Thus, as illustrated in FIG. 2 the system 200 for transmitting data comprises: a plurality of parallel transmission channels 222a, 222b, and 222c, each receiving interleaved data words constituting a data packet or data block. Each channel includes a corresponding check sum data generator 220 to compute check sum data for its corresponding sequence of data words. A logic circuit 215 is responsive to the interleaved data words from each channel for performing an arithmetic operation (e.g. exclusive-or) on the data words from channels to generate a parity data stream 206 onto a separate channel 222d. Channel 222d also includes a check sum data generator 220d for computing checksum data based on the parity data stream. SEREDES devices 225a, 225b, 225c, 225d downstream from each of the checksum data generators encode the data and checksum from each channel for transmission via transmitter arrangement 230 over a network 235.

The system 200 further comprises a receiver arrangement for receiving data including a plurality of reception channels 242e, 242f, 242g and 242h having associated decoders for decoding the received channel data from each of the channels; and respective check sum data check logic modules 250 to compute check sum data associated with received decoded data. Error detection and correction control module 255 receives the output checksum data from each corresponding CRC module 250e, 250f, 250g, and 250h and compares the computed check sum data with reference data (e.g. the received and decoded checksum data). Based on the comparison, if it is determined that only one data channel has a detected error, then module 255 causes channel selection and error recovery logic module 265 to read the buffers from the error free channels and perform an XOR operation on the data to regenerate the data words from the detected error channel. Upon completion, all of the channel data is re-aligned (e.g. temporal re-alignment of the data for the transmitted/received data packet) to ensure the data words constituting the packet(s) are in the correct order via channel resynchronization module 270 and provided to system memory 275 for further processing by DMA engine 260.

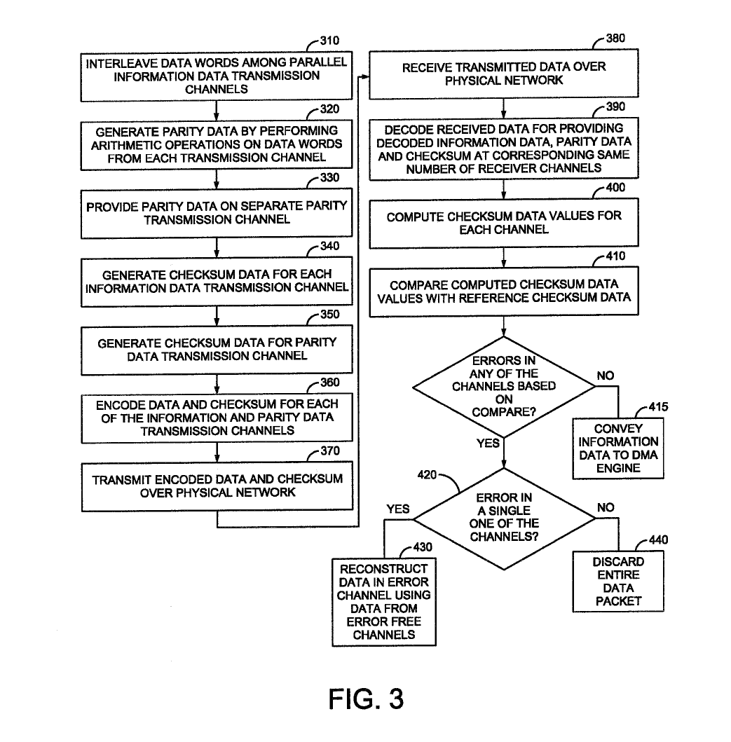

Referring now to FIG. 3, the invention herein is embodied in a process for error correction of data in a data packet containing a plurality of data words, comprising interleaving (310) the data words among a plurality of parallel data transmission channels; generating parity data (320) by performing an arithmetic operation (XOR) on data words from each transmission channel; providing the parity data in a separate parity transmission channel (330); generating checksum data (340) for each transmission data channel according to the channel data words; generating checksum data (350) for the transmission parity channel according to the parity data words; encoding (360) the data and checksum for each of the data transmission channels and parity transmission channel and transmitting (370) the encoded data over a physical network. The process further includes receiving (380) the transmitted data and decoding (390) the received data (including checksum data) at a corresponding same number of parallel receiver channels for providing decoded information data, parity data and checksum; computing (400) check sum data based on the decoded information data words for each of the received channels including the parity channel and comparing (410) the computed checksum data with a reference (e.g. the decoded checksum data from blocks 340, 350). If the check sum comparison indicates no errors, then the channel information data is conveyed (415) to the DMA engine for further processing. Based on the comparison, if an error in a single channel (420) is determined; then correcting (430) the error in the identified channel by reconstructing the data in that channel using the data from the other error free channels, re-synchronizing the corrected data with the data in the remaining channels, and conveying the corrected and resynchronized channel information data to the DMA engine. If errors in more than one channel are identified, then the entire packet is discarded (440).

Thus, embodiments of the present invention illustrate that by placing information data (e.g. interleaving data words) on three transmission channels and placing parity data words on a fourth transmission channel, then errors occurring on any single channel can be recovered. This technique can extend all the way to having a channel fail completely, though further errors will not be recovered. The parity data words transmitted on the parity channel may be computed via a very simple and inexpensive “exclusive or” operation. Furthermore, the system and method of the present invention operates without the complexities associated with conventional data buffering software protocols for error detection and retransmission requests, forward error correction data with the data; use of fully redundant networks, simply acceptance of error conditions.

While the present invention has been described with reference to the illustrative embodiments, this description is not intended to be construed in a limiting sense. Various modifications of the illustrative embodiments, as well as other embodiments of the invention, will be apparent to those skilled in the art on reference to this description. For example, while one possible implementation uses four lanes or channels such as an LX4 or CX4 implementation of a 10-gigabit Ethernet, applications other than Ethernet implementations are also contemplated. Further, while the present invention lends itself to digital radar applications and radar digital data transmission and processing, other applications for the present error transmission and recovery system are also contemplated. It is therefore contemplated that the appended claims will cover any such modifications or embodiments as fall within the true scope of the invention.

We claim:

1. A system for correcting errors in information data constituting a data block transmitted over multiple transmission channels, comprising:
a plurality of parallel transmission channels conveying interleaved information data of said data block, the channels having associated check sum devices to compute a check sum associated with the information data conveyed via the channels;
a processor for computing parity data based on the interleaved information data from the parallel transmission channels;
a parity channel in parallel with the transmission channels and having an associated check sum device for transmitting the parity data and check sum data associated with said parity data;
a transmitter arrangement which transfers the channel information data and channel checksum for each of said plurality of transmission channels, and said channel parity data and parity checksum for said parity channel, over a network;
a corresponding plurality of reception channels having associated checksum devices to compute check sums associated with said transmitted information data, including a corresponding parity channel for receiving said transmitted parity data and associated parity check sum, said corresponding channel having an associated checksum device to compute a checksum associated with said transmitted parity data; and
a logic circuit that compares the computed check sum of the information and parity data received from the network with reference data, wherein if an error is determined in only one of said reception channels based on said comparison, and not in said parity channel, said logic circuit causes a recovery circuit to reconstruct the information data in said only one data channel according to the information data received from said remaining data channels and the received parity data.

2. The system of claim 1, wherein the transmitter arrangement includes an encoding device within each of said plurality of data channels and said parity channel downstream of the checksum devices for encoding said data for transmission over the network.

3. The system of claim 2, wherein the encoding device includes a serializer/deserializer that converts parallel data to serial data for transmission over the network.

4. The system of claim 1, wherein the processor for computing parity data based on said information data comprises an exclusive-or operation on interleaved data words for each data transmission channel.

5. The system of claim 1, wherein each of said corresponding receiver channels further comprises a decoding device for decoding said data previously encoded, said decoding device located upstream of said checksum device.

6. The system of claim 1, wherein said recovery circuit includes a recovery processor adapted to perform exclusive-or operation on data words from said error free information data channels and error free parity data channel to reconstruct the information data in said only one data channel having at least one detected error.

7. The system of claim 6, wherein the recovery processor comprises an FPGA.

8. The system of claim 6, wherein the recovery processor comprises an ASIC.

9. A method for error correction of data in a data packet containing a plurality of data words, comprising:
interleaving the data words among a plurality of parallel data transmission channels;
for each of said plurality of transmission channels, generating checksum data according to the channel data words;
generating parity data words using said interleaved data words from each transmission channel;
providing the parity data words in a separate parallel parity transmission channel;
generating checksum data for the transmission parity channel according to the parity data words;
encoding the data and checksum for each of the data transmission channels and parity transmission channels; and
converting said data words in said parallel channels to a serial arrangement of data for transmission over a physical network;
receiving the transmitted data and decoding the received data at a corresponding number of receiver channels to obtain decoded information data, parity data and checksum;
determining check sum data from the data words received for each of the channels;
comparing the received checksum data with the determined check sum data, and if the check sum comparison indicates an error in a single receive channel, and not in the receive parity channel, then correcting the errors in the identified channel by reconstructing the data words in that channel using the data words from the other error free channels.

10. The method of claim 9, wherein the generating parity data words using said interleaved data words from each transmission channel comprises performing exclusive-or operations on said data words.

11. The method of claim 10, wherein reconstructing the data words in the error channel using the data words from the other error free channels comprises performing exclusive-or operations on said data words of said other error free channels.

12. The method of claim 11, further comprising temporally re-aligning said channel data after said reconstruction.

13. A method for transmitting information data blocks over a network comprising:
interleaving among a plurality of parallel data transmission channels information data words constituting a block of information data;
generating for each parallel channel sets of check sum data associated with the information data words;
computing parity data words associated with the interleaved information data words;
generating for said parity channel check sum data associated with the parity data words;
using one channel for transmitting the parity data words;
transmitting the information data words, the parity data words and associated check sum data over a physical network;
receiving from the physical network data comprising the information data words, the parity data words and associated check sum data;
generating a second set of check sum data associated with the received information data words for each of the plurality of transmission channels, and for the received parity data words for the transmitted parity data channel;
comparing the second set of check sum data to the first set of check sum data;
and if the check sum comparison identifies an error in an information data word in only a single channel of said plurality of information transmission channels and no error in said parity transmission channel; then correcting said error using said information and parity data words of said error free channels.

14. The method of claim 13, wherein the step of computing parity data words comprises performing exclusive-or operations on the interleaved information data words of the information data channels.

15. The method of claim 14, further comprising encoding the information data words and parity data words prior to transmitting over the physical network.

16. The method of claim 15, further comprising decoding the received data received from the physical network.

17. The method of claim 13, wherein computing a plurality of parity codes associated with the data comprises an exclusive-or computation.

18. A system for transmitting information data packets over a network:
a plurality of parallel transmission channels, each receiving interleaved data words constituting said data packets, each of said channels including a corresponding check sum data generator to compute check sum data for a corresponding sequence of data words;
a logic circuit responsive to the interleaved data words of each said channel for performing an arithmetic operation on the data words from those channels to generate a parity data stream onto a separate channel;
a check sum data generator for computing checksum data based on the parity data stream;
an encoder device downstream from each said checksum data generator for encoding the data and checksum from each channel for serial transmission via a transmitter arrangement over a network.

19. A system for correcting errors in information data from a data block transmitted over multiple transmissions channels comprising:
a receiver arrangement for receiving data, said arrangement having a plurality of parallel reception channels having associated decoders for decoding the received channel data including information data and checksum reference data from each of the channels;
a check sum logic module associated with each said channel to compute check sum data associated with received decoded information data;
an error detection and correction control module associated with each said channel, said module receiving the output checksum data from each of said checksum logic module and comparing the computed check sum data with said checksum reference data to determine channel error detections;
wherein if it is determined that only one data channel has a detected error, and the detected error is not in the parity channel, then said error detection and correction control module causes a channel selection and error recovery logic module to regenerate the data words from the detected error channel using the data words of the error free channels and the parity channel.

20. The system of claim 18, wherein the channel selection and error recovery logic module reads data buffers from the error free channels and parity channel and performs exclusive-or operations for recovering the data associated with the single error channel.

21. The system of claim 18, further comprising a channel resynchronization module responsive to the channel selection and error recovery module for temporally re-aligning the channel data words constituting the data block and providing to a memory.
